(19) United States
(12) Patent Application Publication
(10) Pub. No.: US 2004/0241897 A1
(43) Pub. Date: Dec. 2, 2004

(54) Edge-illuminated refracting-facet type light receiving device and method for manufacturing the same

(76) Inventors: Do-Young Rhee, Seoul (KR); Seung-Kee Yang, Suwon-shi (KR)

Correspondence Address: CHA & REITER, LLC, 210 ROUTE 4 EAST STE 103, PARAMUS, NJ, 07652, US

(21) Appl. No.: 10/744,621

(22) Filed: Dec. 23, 2003

(30) Foreign Application Priority Data
May 26, 2003 (KR) 2003-33458

(51) Int. Cl. H01L 21/00

(52) U.S. Cl. 438/69

(57) ABSTRACT

Disclosed are an edge-illuminated refracting-facet type light receiving device and a fabricating method thereof. The edge-illuminated refracting-facet type light receiving device has a semiconductor substrate, a photo-absorption layer formed on the semiconductor substrate, a first window layer entirely formed on an upper surface of the photo-absorption layer, a second window layer formed on an upper surface of the first window layer and having a light incident plane, which is inclined at a predetermined angle with respect to the photo-absorption layer in such a manner that light refracted at the light incident plane is incident into the photo-absorption layer, a first conductive metal layer in contact with the second window layer, and a second conductive metal layer, which is different from the first conductive metal layer, formed at a bottom surface of the semiconductor substrate.

### CLAIM OF PRIORITY

This application claims priority to an application entitled “Edge-illuminated refracting-facet type light receiving device and method for manufacturing the same,” filed in the Korean Intellectual Property Office on May 26, 2003 and assigned Serial No. 2003-33458, the contents of which are hereby incorporated by reference.

### BACKGROUND OF THE INVENTION

1. Field of the Invention

The present invention relates to a light receiving device for converting an optical signal generated from a light source into an electric signal, and more particularly to an edge-illuminated refracting-facet type light receiving device and a method for manufacturing the same.

2. Description of the Related Art

An optical coupling serves to convert an optical signal into an electric signal by guiding light radiated from a light source, such as a laser diode, optical fiber, and a PLC (planar lightwave circuit) device, into a light receiving element via a light path without causing light loss.

Various studies have shown that a vertical photo diode has a superior reliability than a waveguide photo diode. Typically, when forming a package containing the vertical photo diode, an optical coupling of the vertical photo diode requires to be achieved through a three-dimensional way. That is, it is required to align the vertical photo diode up to a vertical position of an optical device when assembling the vertical photo diode into the package.

Recently, in order to fabricate optical modules at an inexpensive cost, a full-automation system is implemented using a chip mounting method. In this fabrication method, two-dimensional optical couplings are required between a laser diode and a photo diode (LD to PD), optical fiber and a photo diode (fiber to PD), and a PLC and a photo diode (PLC to PD).

FIG. 1 is a sectional view showing the structure of a conventional photo detector using the two-dimensional optical coupling. The photo detector is a light receiving device having an edge-illuminated refracting-facet structure and includes an InP substrate 1, a light incident plane 2, an n-InP 3, a photo-absorption layer 4, a p-InP 5, a p-electrode 6, and an n-electrode 7. A light incident plane 2 of the substrate 1, into which light is incident, is subject to a wet etching process so that the light incident plane 2 can have an angled facet, forming a predetermined angle θ with respect to the photo-absorption layer 4.

In operation, light is refracted at the light incident plane 2 of the substrate 1 so that light is directed into the photo-absorption layer 4. The effective absorption length of light is increased and the receiving sensitivity is improved if the light is incident into the photo-absorption layer 4 through a refracting light at the light incident plane 2 of the substrate 1 as compared with a case, in which light is vertically incident into the photo-absorption layer 4.

However, the conventional photo-detector requires a chemical etching process to form the angled facet of the light incident plane, so the reproducibility and the uniformity of devices suffer. In addition, when an anti-reflective coating layer is deposited on the angled mesa-etch surface to reduce the reflection of light, the conventional structure requires to install a bar vertically so that the process becomes complicated, thereby lowering the productivity.

### SUMMARY OF THE INVENTION

Accordingly, the present invention has been made to solve the above-mentioned problems occurring in the prior art and provides additional advantages, by providing an edge-illuminated refracting-facet type light receiving device and a method for manufacturing the same that is capable of increasing the effective absorption length of the light incident into a photo-absorption layer, without requiring a chemical etching process.

In one embodiment, an edge-illuminated refracting-facet type light receiving device is provided and includes: a semiconductor substrate; a photo-absorption layer formed on the semiconductor substrate; a first window layer entirely formed on the upper surface of the photo-absorption layer; a second window layer selectively formed on the upper surface of the first window layer and having a light incident plane, which is inclined when forming a predetermined angle with respect to the photo-absorption layer in such a manner that the light refracted at the light incident plane is incident into the photo-absorption layer; a first conductive metal layer making contact with the second window layer; and a second conductive metal layer, which is different from the first conductive metal layer, and formed at the bottom surface of the semiconductor substrate.

According to a preferred embodiment of the present invention, an anti-reflective layer is formed at the light incident plane of the second window layer. The second window layer has a mesa structure including four angled facets having a predetermined angle. The second window layer includes a (111) plane formed through a selective epitaxial growing process. The first metal layer is formed on the entire surface of the semiconductor substrate except for the light incident plane into which light is incident.

In another embodiment, a method of fabricating an edge-illuminated refracting-facet type light receiving device is provided and includes the steps of: forming a photo-absorption layer and a first window layer on a semiconductor substrate; selectively forming a second window layer on the upper surface of the first window layer in such a manner that a light incident plane of the second window layer forms a predetermined angle with respect to the photo-absorption layer to allow the light refracted at the light incident plane to be incident into the photo-absorption layer; forming a first conductive metal layer such that the first conductive metal layer makes contact with the second window layer; and forming a second conductive metal layer, which is different from the first conductive metal layer, at the bottom surface of the semiconductor substrate. The method further includes a step of forming an anti-reflective layer on the light incident plane of the second window layer.

In order to selectively form the second window layer on the upper portion of the first window layer, a selective epitaxial growing mask is formed on the upper portion of the first window layer in a [110] or [1\overline{1}0] and a second window layer is formed by growing an epitaxial layer on the exposed upper portion of the first window layer using the selective epitaxial growing mask.

### BRIEF DESCRIPTION OF THE DRAWINGS

The above features and advantages of the present invention will be more apparent from the following detailed description taken in conjunction with the accompanying drawings, in which:

FIG. 1 is a sectional view showing a conventional edge-illuminated refracting-facet type photo detector;

FIG. 2 is a view showing a structure of an edge-illuminated refracting-facet type light receiving device according to one embodiment of the present invention;

FIG. 3 is a sectional view taken along line A-A′ shown in FIG. 2;

FIG. 4 is a sectional view showing an optical coupling between a photo diode detector and a PLC light source according to one embodiment of the present invention; and

FIG. 5 is a view for explaining Snell's law.

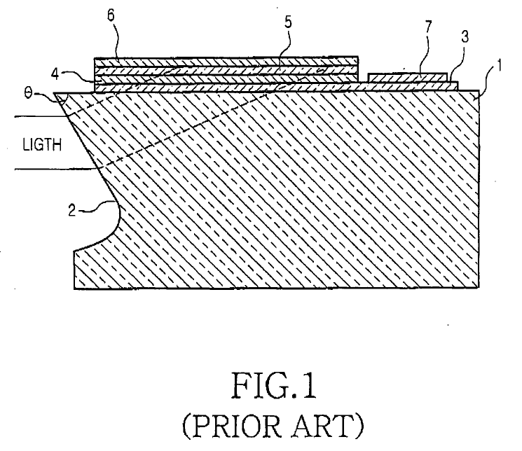

### DETAILED DESCRIPTION OF THE PREFERRED EMBODIMENT

Hereinafter, a preferred embodiment of the present invention will be described with reference to the accompanying drawings. For the purposes of clarity and simplicity, a detailed description of known functions and configurations incorporated herein will be omitted as it may make the subject matter of the present invention unclear.

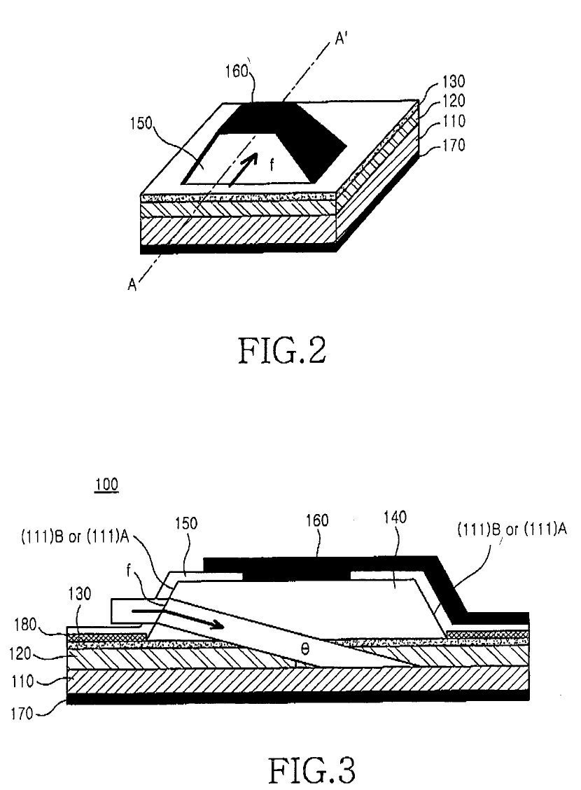

FIG. 2 is a view showing the structure of an edge-illuminated refracting-facet type light receiving device according to one embodiment of the present invention, and FIG. 3 is a sectional view taken along line A-A′ shown in FIG. 2.

Referring to FIGS. 2 and 3, an edge-illuminated refracting-facet type light receiving device 100 according to the embodiment of the present invention includes a first conductive semiconductor substrate 110, a photo-absorption layer 120 formed on the first conductive semiconductor substrate 110, a first window layer 130 formed on the photo-absorption layer 120, a second window layer 140 formed on the first window layer 130 and having a light incident plane formed at a predetermined angle θ with respect to the photo-absorption layer 120 in such a manner that light refracted at the light incident plane is incident into the photo-absorption layer 120, a first metal layer 160, and a second metal layer 170. Further, an anti-reflective layer 150 is formed on the light incident plane of the second window layer 140.

The first conductive semiconductor substrate 110 is a type of an n-InP semiconductor layer having an InP buffer layer.

The photo-absorption layer 120 consists of material having a lower energy than the band-gap energy of a wavelength of an optical signal to be absorbed into the photo-absorption layer 120. Generally, the photo-absorption layer 120 includes u-InGaAs material.

In contrast, the first window layer 130 consists of material having a higher energy than band-gap energy of a wavelength of an optical signal to be absorbed into the first window layer 130. The first window layer 130 includes p-InP conductive material that is different from the first conductive semiconductor substrate 110.

The second window layer 140 is selectively formed on the upper surface of the first window layer 130. The second window layer 140 includes the light incident plane f having a mesa structure, which enables to form a predetermined angle θ with respect to the photo-absorption layer 120 so that the light is incident into the photo-absorption layer 120 when refracted at the light incident plane f. By forming this type of an angled light incident plane, light is incident into the photo-absorption layer 120 when refracted at the light incident plane so that effective absorption length of light is increased as compared with a case, in which light is vertically incident into the photo-absorption layer 120 as in the prior art.

The second window layer 140 having the mesa structure can be formed through a selective epitaxial growing process. Firstly, an InP buffer layer (not shown), the u-InGaAs photo-absorption layer 120, and the InP window layer 130 are sequentially formed on the InP substrate 110 through a single crystal growing process. Then, after depositing an insulating layer including SiN_{X} and SiO₂ 180 on the InP window layer 130, the insulating layer is aligned in the [110] or [1\overline{1}0] direction through a photolithography process. The insulating layer aligned in the [110] or [1\overline{1}0] direction is used as a mask for the selective epitaxial growing. If a single crystal growing of the first window layer is carried out using the selective epitaxial growing mask, a growing facet is formed in the (111)B plane or (111)A plane. The (111) plane formed through the selective epitaxial growing process is inclined with respect to the (100) plane at an angle of 54.4°.

Referring back to FIGS. 2 and 3, the anti-reflective layer 150 is formed on the light incident plane of the second window layer to allow a light signal radiated from a light source, such as a laser, optical fiber and a PLC, to pass therethrough without reflecting light signal. In an alternate embodiment, the anti-reflective layer 150 maybe be omitted. For example, in a case of an MPD (monitor photo diode) monitoring the optical signal, the anti-reflective layer is not formed for the simplicity and fabrication process convenience. When the anti-reflective layer 150 is omitted, 30 to 35% of the light signal is reflected from the light incident plane when light is incident into the light incident plane. As such, the anti-reflective layer 150 has to be selectively used considering the light loss, process efficiency, and characteristics of optical devices to compensate for the light loss.

The first and second metal layers 160 and 170 are used as electrodes for detecting photo-electric conversion signals through external circuits. If metal is deposited on the entire area of the substrate except for the light incident plane, into which light is incident, incident light can be reflected to the photo-absorption layer 120. As a result, a sufficient coupling tolerance can be obtained when performing the optical coupling.

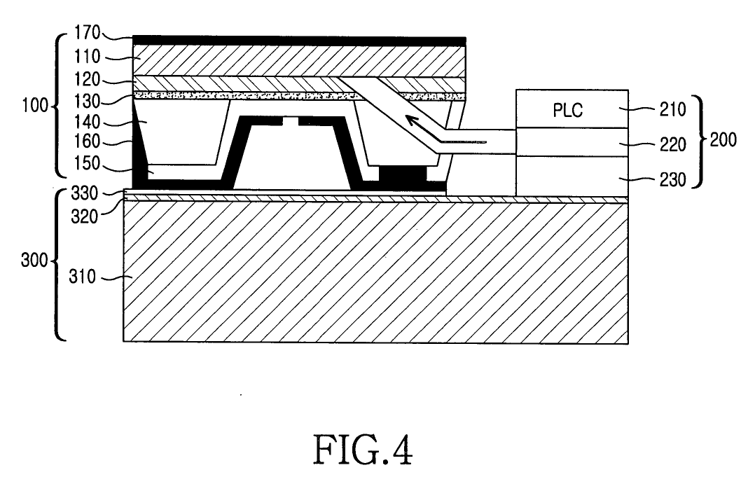

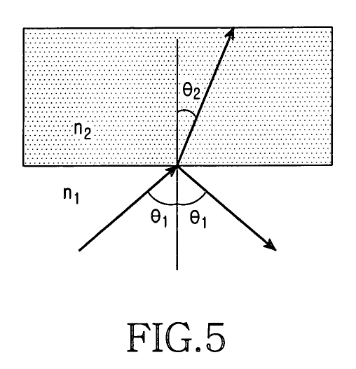

Hereinafter, an operation of the edge-illuminated refracting-facet type light receiving device having the above structure will be described with reference to FIGS. 4 and 5.

FIG. 4 is a sectional view showing an optical coupling between a photo diode detector and a PLC light source 200 according to one embodiment of the present invention, and FIG. 5 explains the Snell's law to illustrate the teachings of the present invention. In the figures, reference numerals 210, 220, 230, 300, 310, 320 and 330 represent an upper clad, a core, a lower clad, a substrate, a silicon substrate, a SiO₂ layer, and a metal layer, respectively.

Referring to FIG. 4, a light signal radiated from the PLC light source 200 is incident into the light incident plane f of the second window layer 140 through the anti-reflective layer 150. If the light incident plane f of the second window layer 140 is the (111) plane having an incline angle of 54.4° with respect to the (100) plane, the optical signal progressing in parallel to the (100) plane makes contact with the (111) plane while forming an angle of 35.6° (90°-54.4°) with respect to the (111) plane, so that refraction occurs. Such refraction occurs whenever incident light passes through an interfacial surface formed between mediums having different properties. Snell's law defines the refraction of light behavior when light passes through the interfacial surface formed between mediums having different properties.

Referring to FIG. 5, n₁ sin θ₁=n₂ sin θ₂ (Snell's law), wherein is n₁ a refractive index of a first medium, n₂ is a refractive index of a second medium, θ₁ is an incident angle of light with respect to an interfacial surface between the first and second mediums, and θ₂ is a refractive angle of light transmitting into the second medium.

When light is incident into the photo-absorption layer with a predetermined refractive angle θ, effective absorption length is defined as T/sin θ, wherein T is thickness of the photo-absorption layer. For example, when the thickness of the photo-absorption layer is 1 μm, and θ is 25°, effective absorption length is 2.36 μm. Thus, it is possible to achieve a superior responsiveness even if a thin photo-absorption layer is applied.

As described above, according to the present invention, the light incident plane of the light receiving device has an inclined structure so that effective absorption length of light incident into the photo-absorption layer can be increased. Accordingly, it is possible to remarkably reduce the thickness of the photo-absorption layer as compared with a case, in which light is vertically incident into the photo-absorption layer as in the prior art. In addition, transition time of a carrier can be reduced, so an operational speed of the light receiving device can be improved. Furthermore, according to the method for fabricating the light receiving device of the present invention, the light incident plane of the light receiving device can be formed in an inclined structure through a selective epitaxial growing process. Thus, the chemical etching process for forming an angled facet as in the prior artisan not required, so the reproducibility and uniformity of the light receiving device can be remarkably improved.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An edge-illuminated refracting-facet type light receiving device comprising:
a semiconductor substrate;
a photo-absorption layer formed on the semiconductor substrate;
a first window layer formed on an upper surface of the photo-absorption layer; and
a second window layer having a light incident plane formed on an upper surface of the first window layer, the light incident plane having a predetermined angle with respect to the photo-absorption layer to enable light refracted at the light incident plane to be incident into the photo-absorption layer.

2. The edge-illuminated refracting-facet type light receiving device as claimed in claim 1, further comprising:
a first conductive metal layer in contact with the second window layer; and
a second conductive metal layer formed at the bottom surface of the semiconductor substrate.

3. The edge-illuminated refracting-facet type light receiving device as claimed in claim 1, further comprising an anti-reflective layer formed at the light incident plane of the second window layer.

4. The edge-illuminated refracting-facet type light receiving device as claimed in claim 1, wherein the second window layer has a mesa structure including four angled facets having a predetermined angle.

5. The edge-illuminated refracting-facet type light receiving device as claimed in claim 1, wherein the second window layer includes a (111) plane formed through a selective epitaxial growing process.

6. The edge-illuminated refracting-facet type light receiving device as claimed in claim 1, wherein the first metal layer is formed on an entire surface of the semiconductor substrate except for the light incident plane into which light is incident.

7. The edge-illuminated refracting-facet type light receiving device as claimed in claim 1, wherein the first semiconductor substrate 110 comprises an n-InP semiconductor layer having an InP buffer layer.

8. The edge-illuminated refracting-facet type light receiving device as claimed in claim 1, wherein the photo-absorption layer consists of material having a lower energy than the band-gap energy of a wavelength of an optical signal to be absorbed into the photo-absorption layer.

9. The edge-illuminated refracting-facet type light receiving device as claimed in claim 1, wherein the photo-absorption layer comprises u-InGaAs material.

10. The edge-illuminated refracting-facet type light receiving device as claimed in claim 1, wherein the first window layer having a higher energy than band-gap energy of a wavelength of an optical signal to be absorbed into the first window layer.

11. The edge-illuminated refracting-facet type light receiving device as claimed in claim 1, wherein the first window layer comprises p-InP conductive material.

12. A method for fabricating an edge-illuminated refracting-facet type light receiving device, the method comprising the steps of:
a) forming a photo-absorption layer and a first window layer on a semiconductor substrate;
b) forming a second window layer on an upper surface of the first window layer in such a manner that a light incident plane of the second window layer forms a predetermined angle with respect to the photo-absorption layer to allow light refracted at the light incident plane to be incident into the photo-absorption layer;
c) forming a first conductive metal layer in contact with the second window layer; and
d) forming a second conductive metal layer at a bottom surface of the semiconductor substrate.

13. The method as claimed in claim 12, further comprising a step of forming an anti-reflective layer on the light incident plane of the second window layer.

14. The method as claimed in claim 12, wherein step a) comprises the substeps of:
i) forming a selective epitaxial growing mask on an upper portion of the first window layer in a [110] or a [1\overline{1}0] direction; and
ii) forming a second window layer by growing an epitaxial layer on an exposed upper portion of the first window layer using the selective epitaxial growing mask.

15. The method as claimed in claim 14, wherein step i) is achieved through a photolithography process.

16. The method as claimed in claim 12, wherein the second window layer has a (111) plane formed through a selective epitaxial growing process.

17. The method as claimed in claim 12, wherein step c) is achieved through depositing a first conductive metal on an entire surface of the semiconductor substrate except for the light incident layer, into which light is incident.
